(19) United States
(12) Patent Application Publication
(10) Pub. No.: US 2006/0043385 A1
(43) Pub. Date: Mar. 2, 2006

(54) White light emitting diode of a blue and yellow light emitting (structure) layer stacked structure and method of manufacturing the same

(75) Inventors: Xiaoliang Wang, Beijing (CN); Lunchun Guo, Beijing (CN); Junxi Wang, Beijing (CN); Jinmin Li, Beijing (CN); Yiping Zeng, Beijing (CN)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(73) Assignee: Institute of Semiconductors, Chinese Academy of Sciences

(21) Appl. No.: 11/184,168

(22) Filed: Jul. 19, 2005

(30) Foreign Application Priority Data
Aug. 27, 2004 (CN) 2004100571502

(51) Int. Cl. H01L 33/00

(52) U.S. Cl. 257/79

(57) ABSTRACT

A white LED of a blue and yellow light emitting (structure) layer stacked structure includes a sapphire substrate, or gallium nitride substrate, or silicon carbide substrate, or silicon substrate; a buffer layer formed on the substrate; an N type gallium nitride epitaxial layer formed on the buffer layer; an N doped AlₐIn_{b}Ga_{1-a-b}N quarternary alloy formed on the N type gallium nitride epitaxial layer; a blue light emitting structure layer which contains one or more InₓGa₁₋ₓN/AlₐIn_{b}Ga_{1-a-b}N quantum well(s) formed on the N type AlₐIn_{b}Ga_{1-a-b}N layer; a yellow light emitting structure layer which contains one or more In_{y}Ga_{1-y}N/AlₐIn_{b}Ga_{1-a-b}N quantum well(s) formed on the InₓGa₁₋ₓN/AlₐIn_{b}Ga_{1-a-b}N quantum well structure; or alternatively, a yellow light emitting structure layer which contains one or more In_{y}Ga_{1-y}N/AlₐIn_{b}Ga_{1-a-b}N quantum well(s) being formed on the N type AlₐIn_{b}Ga_{1-a-b}N layer first, and then a blue light emitting structure layer which contains one or more InₓGa₁₋ₓN/AlₐIn_{b}Ga_{1-a-b}N quantum well(s) being formed on the In_{y}Ga_{1-y}N/AlₐIn_{b}Ga_{1-a-b}N quantum well(s) structure; a P type Al_{0.1}Ga_{0.9}N and a P type GaN cap layer formed on the top.

### CROSS-REFERENCE TO RELATED APPLICATIONS

This application claims priority to Chinese Application Serial No. 2004100571502, filed Aug. 27, 2004, which application is hereby incorporated by reference.

### BACKGROUND OF THE INVENTION

1. The Field of the Invention

The present invention relates to a semiconductor technology, more particularly, to a white light emitting diode of a blue and yellow light emitting (structure) layer stacked structure and a method for manufacturing the same.

2. The Relevant Technology

As solid light sources, compound semiconductor light emitting devices (LEDs) were developed from 1960s. The first GaN-based blue light emitting diode came into birth in 1992; and in 1994, GaN-based blue LEDs were put into practice. GaN-based blue, green LED products are key devices which are necessary to a large screen full color display, and the presence of which essentially solved the problem of LEDs being absent of one or more primary colors. LEDs have advantages of small volume, high emitting efficiency, explosion proof, power saving, and long lifetime and so on. High brightness GaN based LEDs have significant potential applications in the large screen displaying, vehicles and traffics, LCD back light sources and illuminations. While enriching the colors, the most attractive prospect of high brightness GaN based LEDs is perhaps to be used in normal white light illumination. The realization of semiconductor illumination is of great significance no inferior to Edison's incandescent lamps. However, the GaN-based LED suffers from low power and high price, preventing it from taking place of normal illumination, therefore at present the most important task is to improve the power of LED and reduce the cost of manufacturing.

Current white LEDs utilize short wavelength light to activate phosphor of various colors (or single color), and the mixture of lights of various colors produces white light; or alternatively, utilize three diodes packaged together, which emits red, green, blue light respectively. However, utilizing short wavelength light to activate phosphor will lose part of the power, and if the ultraviolet light is used as activating light source and the package is not very well, the ultraviolet light will leak from the package, thus causing harm to users. Furthermore, the usage of phosphor increases the complexity of package processes, and thus increases the cost of manufacturing white LEDs. The cost of manufacturing will be even higher if the white LEDs are manufactured by packaging three red, green and blue LED chips together. The design of present invention provides a white LED of blue and yellow quantum wells stacked structure, which is cheaper than the two methods described above, and perhaps can cause the price of white LEDs decreased to the price level of blue LEDs with same power.

### SUMMARY OF THE INVENTION

The purpose of the invention is to provide a white light emitting diode of a blue and yellow light emitting (structure) layer stacked structure and a method thereof, with which the price of the white LEDs can be reduced to the price level of the blue LEDs with same power.

A white LED of a blue and yellow light emitting (structure) layer stacked structure according to the present invention comprises:
a sapphire substrate, or gallium nitride substrate, or silicon carbide substrate, or silicon substrate;
a buffer layer formed on the substrate;
an N type gallium nitride epitaxial layer formed on the buffer layer;
an N doped AlₐIn_{b}Ga_{1-a-b}N quarternary alloy formed on the N type gallium nitride epitaxial layer;
a blue light emitting structure layer which contains one or more InₓGa₁₋ₓN/AlₐIn_{b}Ga_{1-a-b}N quantum well(s) formed on the N type AlₐIn_{b}Ga_{1-a-b}N layer;
a yellow light emitting structure layer which contains one or more In_{y}Ga_{1-y}N/AlₐIn_{b}Ga_{1-a-b}N quantum well(s) formed on the blue light emitting structure layer;
or alternatively, a yellow light emitting structure layer which contains one or more In_{y}Ga_{1-y}N/AlₐIn_{b}Ga_{1-a-b}N quantum well(s) being formed on the N type AlₐIn_{b}Ga_{1-a-b}N layer first, and then a blue light emitting structure layer which contains one or more InₓGa₁₋ₓN/AlₐIn_{b}Ga_{1-a-b}N quantum well(s) being formed on the yellow light emitting structure layer;
a P type Al_{0.1}Ga_{0.9}N and a P type GaN cap layer formed on the top.

Preferably, the blue light emitting structure layer is one or more InₓGa₁₋ₓN/AlₐIn_{b}Ga_{1-a-b}N quantum wells; the yellow light emitting structure layer is one or more In_{y}Ga_{1-y}N/AlₐIn_{b}Ga_{1-a-b}N quantum wells, and the mixture of the blue light emitted by the InₓGa₁₋ₓN/AlₐIn_{b}Ga_{1-a-b}N quantum well(s) and the yellow light emitted by the In_{y}Ga_{1-y}N/AlₐIn_{b}Ga_{1-a-b}N quantum well(s) produces the white light.

Preferably, the thickness of the N type AlₐIn_{b}Ga_{1-a-b}N layer is 1 μm-3 μm, and in the N type AlₐIn_{b}Ga_{1-a-b}N layer, the content of AlN, a, is 0.2-0.3, and the content of the InN, b, is 0.1-0.25.

Preferably, in the blue light emitting InₓGa₁₋ₓN/AlₐIn_{b}Ga_{1-a-b}N quantum well, the content of the InN in the InₓGa₁₋ₓN potential well layer, x, is 0.1-0.28; the thickness of the InₓGa₁₋ₓN potential well layer is 1 nm-8 nm; the ratio of components of the AlₐIn_{b}Ga_{1-a-b}N potential barrier layer is the same as that of the N type AlₐIn_{b}Ga_{1-a-b}Nlayer, and the thickness thereof is 3-12 nm.

Preferably, in the white LED of such a blue, yellow light emitting (structure) layer stacked structure of the present invention, in the yellow light emitting In_{y}Ga_{1-y}N/AlₐIn_{b}Ga_{1-a-b}N quantum well, the content of the InN in the In_{y}Ga_{1-y}N potential well layer, y, is 0.3-0.55, and the thickness of the In_{y}Ga_{1-y}N potential well layer is 1 nm-8 nm; the ratio of components of the AlₐIn_{b}Ga_{1-a-b}N potential barrier layer is the same as that of the N type AlₐIn_{b}Ga_{1-a-b}N quarternary alloy, and the thickness thereof is 3-12 nm.

Preferably, in the white LED of such a blue, yellow light emitting (structure) layer stacked structure of the present invention, the wavelength of blue light emitted by the InₓGa₁₋ₓN/AlₐIn_{b}Ga_{1-a-b}N quantum well is in a range from 430 nm to 495 nm, and the wavelength of yellow light emitted by the In_{y}Ga_{1-y}N/AlₐIn_{b}Ga_{1-a-b}N quantum well is in a range from 562 nm to 585 nm.

A method for manufacturing a white LED of a blue and yellow light emitting (structure) layer stacked structure according to the present invention comprises steps of:
growing a buffer layer and an N type gallium nitride epitaxial layer on a sapphire substrate, or gallium nitride substrate, or silicon carbide substrate, or silicon substrate;
growing an N doped AlₐIn_{b}Ga_{1-a-b}N quarternary alloy, whose thickness is 1 μm-3 μm, on the N type GaN;
growing a blue light emitting structure layer which contains one or more InₓGa₁₋ₓN/AlₐIn_{b}Ga_{1-a-b}N quantum well(s) on the N type AlₐIn_{b}Ga_{1-a-b}N;
growing a yellow light emitting structure layer which contains one or more In_{y}Ga_{1-y}N/AlₐIn_{b}Ga_{1-a-b}N quantum well(s) on the InₓGa₁₋ₓN/AlₐIn_{b}Ga_{1-a-b}N blue light emitting structure layer;
growing a P type Al_{0.1}Ga_{0.9}N and a P type GaN cap layer.

Preferably, in the AlₐIn_{b}Ga_{1-a-b}N quarternary alloy, the content of the AlN, a, is 0.2-0.3, the content of InN, b, is 0.1-0.25, and the content of the GaN is 1-a-b.

Preferably, the content of InN in the InₓGa₁₋ₓN potential well layer, x, is 0.1-0.28, and the thickness of the InₓGa₁₋ₓN potential well layer is 1 nm-8 nm; the ratio of components of the AlₐIn_{b}Ga_{1-a-b}N potential barrier layer is the same as that of the N type AlₐIn_{b}Ga_{1-a-b}N quarternary alloy, and the thickness thereof is 3-12 nm.

Preferably, the content of InN in the In_{y}Ga_{1-y}N potential well layer, y, is 0.3-0.55, and the thickness of the In_{y}Ga_{1-y}N potential well layer is 1 nm-8 nm; the ratio of components of the AlₐIn_{b}Ga_{1-a-b}N potential barrier layer is the same as that of the N type AlₐIn_{b}Ga_{1-a-b}N layer, and the thickness thereof is 3-12 nm.

The present invention provides a new method for causing LED to generate white light, advantages of which are:

(1) The InₓGa₁₋ₓN/AlₐIn_{b}Ga_{1-a-b}N quantum well(s) which can emit blue light and the In_{y}Ga_{1-y}N/AlₐIn_{b}Ga_{1-a-b}N quantum well(s) which can emit yellow light are grown on the same LED chip, and after the LED is powered on, the mixture of the blue light of certain intensity emitted by the InₓGa₁₋ₓN/AlₐIn_{b}Ga_{1-a-b}N quantum well and the yellow light of certain intensity emitted by the In_{y}Ga_{1-y}N/AlₐIn_{b}Ga_{1-a-b}N quantum produces white light.

(2) Using the AlₐIn_{b}Ga_{1-a-b}N quarternary alloy as the potential barrier layer of the quantum well reduces the lattice mismatching between the potential well layer and the potential barrier layer.

### BRIEF DESCRIPTION OF THE DRAWINGS

The present invention will be clearer from the following description taken in conjunction with the accompanied drawing, in which:

FIG. 1 is a diagram showing the structure of the present invention.

### DETAILED DESCRIPTION OF THE PREFERRED EMBODIMENTS

The key point of the present invention is a design of a blue and yellow light emitting (structure) layer stacked structure and using an AlₐIn_{b}Ga_{1-a-b}N as a potential barrier layer of the quantum wells.

The method is described hereinafter. First, one or more InₓGa₁₋ₓN/AlₐIn_{b}Ga_{1-a-b}N quantum well(s) which can emit blue light are grown on an N type AlₐIn_{b}Ga_{1-a-b}N quarternary alloy whose thickness is 1 μm-3 μm. The reason of using AlₐIn_{b}Ga_{1-a-b}N as the potential barrier layer instead of GaN is that in conventional InGaN/GaN quantum well structure, the potential well InGaN layer suffers a pressure stress because the lattice constant of InN (a=3.533 Å) is larger than that of GaN (a=3.187 Å); and the greater the content of InN in InGaN layer is, the greater the pressure stress is, and when the content of In is greater than a certain value, there occurs a stress release, producing crystal defects, and thus causes lowered emitting efficiency of LED. Furthermore, in conventional InGaN/GaN quantum wells, the emitting efficiency of quantum wells would be lowered by the piezoelectric field induced by piezoelectric polarization effect, which was caused due to the difference of lattice constants between the potential well InGaN layer and the potential barrier GaN layer, so the AlInGaN quarternary alloy, whose band gap and lattice constant are adjustable independently, is used as the barrier layer in place of GaN, to reduce problems caused by the difference of lattice constants between the potential barrier layer and the potential well layer.

After the growth of the InₓGa₁₋ₓN/AlₐIn_{b}Ga_{1-a-b}N blue light emitting quantum well(s), one or more In_{y}Ga_{1-y}N/AlₐIn_{b}Ga_{1-a-b}N quantum well(s) whch can emit yellow light are grown thereon, and finally a P type Al_{0.1}Ga_{0.9}N layer and a P type GaN cap layer are grown.

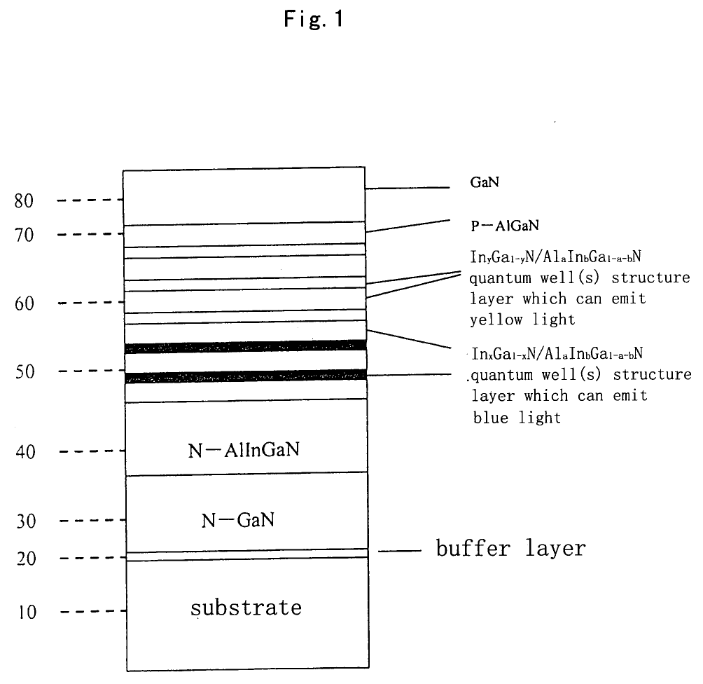

Referring to FIG. 1, a white light emitting diode of a blue and yellow light emitting (structure) layer stacked structure according to the present invention comprises:
A sapphire substrate, or gallium nitride substrate, or silicon carbide substrate, or silicon substrate 10;
A buffer layer 20 formed on the substrate 10;
An N type gallium nitride epitaxial layer 30 formed on the buffer layer 20;
An N type doped AlₐIn_{b}Ga_{1-a-b}N quarternary alloy 40 formed on the N type gallium nitride epitaxial layer 30; wherein the thickness of the N type AlₐIn_{b}Ga_{1-a-b}N layer 40 is 1 μm-3 μm; wherein the content of AlN, a, is 0.2-0.3, and the content of InN, b, is 0.1-0.25;
A blue light emitting structure layer 50 which contains one or more InₓGa₁₋ₓN/AlₐIn_{b}Ga_{1-a-b}N quantum well(s) formed on the N type AlₐIn_{b}Ga_{1-a-b}N quarternary alloy 40;
A yellow light emitting structure layer 60 whch contains one or more In_{y}Ga_{1-y}N/AlₐIn_{b}Ga_{1-a-b}N quantum well(s) formed on the blue light emitting structure layer 50;
or alternatively, a yellow light emitting structure layer which contains one or more In_{y}Ga_{1-y}N/AlₐIn_{b}Ga_{1-a-b}N quantum well(s) is formed on the AlₐIn_{b}Ga_{1-a-b}N quarternary alloy 40 first, and then a blue light emitting structure layer which contains one or more InₓGa₁₋ₓN/AlₐIn_{b}Ga_{1-a-b}N quantum well(s) is formed. The mixture of the blue light generated by the blue light emitting structure layer 50 and the yellow light generated by the yellow light emitting structure layer 60 produces white light. The content of InN in the InₓGa₁₋ₓN potential well of the InₓGa₁₋ₓN/AlₐIn_{b}Ga_{1-a-b}N quantum well(s), x, is within 0.1-0.28. The thickness of the potential well InₓGa₁₋ₓN layer is 1 nm-8 nm; and the ratio of components of the potential barrier AlₐIn_{b}Ga_{1-a-b}N layer is the same as that of the N type AlₐIn_{b}Ga_{1-a-b}N quarternary alloy 40, and the thickness thereof is 3-12 nm.
A P type Al_{0.1}Ga_{0.9}N 70 and a P type GaN cap layer 80 are grown.

In such a white LED of a blue and yellow light emitting (structure) layer stacked structure, the content of InN in the In_{y}Ga_{1-y}N potential well of the In_{y}Ga_{1-y}N/AlₐIn_{b}Ga_{1-a-b}N quantum well(s), y, is within a range of 0.3-0.55, and the thickness of the potential well In_{y}Ga_{1-y}N layer is within a range of 1 nm-8 nm. The ratio of components of the potential barrier AlₐIn_{b}Ga_{1-a-b}N layer is the same as that of the N type AlₐIn_{b}Ga_{1-a-b}N quarternary alloy 40, and the thickness thereof is within a range of 3-12 nm.

In such a white LED of a blue and yellow light emitting (structure) layer stacked structure, the wavelength range of the blue light emitted by the InₓGa₁₋ₓN/AlₐIn_{b}Ga_{1-a-b}N quantum well(s) is in a range from 430 nm to 495 nm, and the wavelength range of the yellow light emitted by In_{y}Ga_{1-y}N/AlₐIn_{b}Ga_{1-a-b}N quantum well(s) is in a range from 562 nm to 585 nm.

A method for manufacturing a white LED of a blue and yellow light emitting (structure) layer stacked structure according to the present invention comprises steps of:
Growing a buffer layer 20 and an N type gallium nitride epitaxial layer 30 on a sapphire substrate, or gallium nitride substrate, or silicon carbide substrate, or silicon substrate 10;
Growing an N doped AlₐIn_{b}Ga_{1-a-b}N quarternary alloy 40, whose thickness is 1 μm-3 μm, on the N type GaN 30;
Growing a blue light emitting structure layer 50 which contains one or more InₓGa₁₋ₓN/AlₐIn_{b}Ga_{1-a-b}N quantum well(s) on the N type AlₐIn_{b}Ga_{1-a-b}N quarternary alloy 40;
Growing a yellow light emitting structure layer 60 which contains one or more In_{y}Ga_{1-y}N/AlₐIn_{b}Ga_{1-a-b}N quantum well(s) on the blue light emitting layer 50;
Growing a P type Al_{0.1}Ga_{0.9}N 70 and a P type GaN cap layer 80.

In the AlₐIn_{b}Ga_{1-a-b}N quarternary alloy 40, the content of AlN, a, is within a range of 0.2-0.3, and the content of InN, b, is within a range of 0.1-0.25, and the content of GaN is 1-a-b.

In such structure, there exists one or more InₓGa₁₋ₓN/AlₐIn_{b}Ga_{1-a-b}N quantum well(s) in the blue light emitting structure layer 50.

The content of InN in the InₓGa₁₋ₓN potential well layer, x, is within a range of 0.1-0.28, and the thickness of the InₓGa₁₋ₓN potential well layer is 1 nm-8 nm; the ratio of components of the AlₐIn_{b}Ga_{1-a-b}N potential barrier layer is the same as that of the N type AlₐIn_{b}Ga_{1-a-b}N quarternary alloy 40, and the thickness thereof is 3-12 nm.

In such structure, there exists one or more In_{y}Ga_{1-y}N/AlₐIn_{b}Ga_{1-a-b}N quantum well(s) in the yellow light emitting structure layer 60.

The content of InN in the In_{y}Ga_{1-y}N potential well layer, y, is within a range of 0.3-0.55, and the thickness of the In_{y}Ga_{1-y}N potential well layer is 1 nm-8 nm; the ratio of components of the AlₐIn_{b}Ga_{1-a-b}N potential barrier layer is the same as that of the N type AlₐIn_{b}Ga_{1-a-b}N quarternary alloy 40, and the thickness thereof is 3-12 nm.

What is claimed is:

1. A white light emitting diode (LED) of a blue and yellow light emitting (structure) layer stacked structure comprises:
a sapphire substrate, or gallium nitride substrate, or silicon carbide substrate, or silicon substrate;
a buffer layer formed on the substrate;
an N type gallium nitride epitaxial layer formed on the buffer layer;
an N doped AlₐIn_{b}Ga_{1-a-b}N quarternary alloy formed on the N type gallium nitride epitaxial layer;
a blue light emitting structure layer which contains one or more InₓGa₁₋ₓN/AlₐIn_{b}Ga_{1-a-b}N quantum well(s) formed on the N type AlₐIn_{b}Ga_{1-a-b}N layer;
a yellow light emitting structure layer which contains one or more In_{y}Ga_{1-y}N/AlₐIn_{b}Ga_{1-a-b}N quantum well(s) formed on the blue light emitting structure layer;
or alternatively, one or more In_{y}Ga_{1-y}N/AlₐIn_{b}Ga_{1-a-b}N quantum well(s) which can emit yellow light being formed on the N type AlₐIn_{b}Ga_{1-a-b}N layer first, and then a blue light emitting structure layer which contains one or more InₓGa₁₋ₓN/AlₐIn_{b}Ga_{1-a-b}N quantum well(s) being formed on the In_{y}Ga_{1-y}N/AlₐIn_{b}Ga_{1-a-b}N quantum well(s) structure layer;
a P type Al_{0.1}Ga_{0.9}N and a P type GaN cap layer formed on the top.

2. The white LED according to claim 1, wherein the blue light emitting structure layer is one or more InₓGa₁₋ₓN/AlₐIn_{b}Ga_{1-a-b}N quantum well(s) which can emit blue light; and the yellow light emitting structure layer is one or more In_{y}Ga_{1-y}N/AlₐIn_{b}Ga_{1-a-b}N quantum well(s) which can emit yellow light, and the mixture of the blue light emitted by the blue light emitting quantum well(s) and the yellow light emitted by the yellow light emitting quantum well(s) produces white light.

3. The white LED according to claim 1, wherein the thickness of the N type AlₐIn_{b}Ga_{1-a-b}N layer is 1 □m^{'}□m; wherein the content of AlN, a, is 0.2-0.3, and the content of InN, b, is 0.1-0.25.

4. The white LED according to claim 1, wherein the content of InN in the InₓGa₁₋ₓN potential well layer of the InₓGa₁₋ₓN/AlₐIn_{b}Ga_{1-a-b}N quantum well(s), x, is 0.1-0.28; the thickness of the InₓGa₁₋ₓN potential well layer is 1 nm-8 nm; the ratio of components of the AlₐIn_{b}Ga_{1-a-b}N potential barrier layer is the same as that of the N type AlₐIn_{b}Ga_{1-a-b}N layer, and the thickness thereof is 3-12 nm.

5. The white LED according to claim 1, wherein in the white LED of the blue, yellow light emitting (structure) layer stacked structure, the content of InN in the In_{y}Ga_{1-y}N potential well layer of the In_{y}Ga_{1-y}N/AlₐIn_{b}Ga_{1-a-b}N quantum well, y, is 0.3-0.55; the thickness of the In_{y}Ga_{1-y}N potential well layer is 1 nm-8 nm; the ratio of components of the AlₐIn_{b}Ga_{1-a-b}N potential barrier layer is the same as that of the N type AlₐIn_{b}Ga_{1-a-b}N layer, and the thickness thereof is 3-12 nm.

6. The white LED according to claim 1, wherein in the white LED of the blue, yellow light emitting (structure) layer stacked structure, the wavelength range of blue light emitted by the InₓGa₁₋ₓN/AlₐIn_{b}Ga_{1-a-b}N quantum well(s) is 430 nm-495 nm, and the wavelength range of yellow light emitted by the In_{y}Ga_{1-y}N/AlₐIn_{b}Ga_{1-a-b}N quantum well(s) is 562 nm-585 nm.

7. A method for manufacturing a white light emitting diode (LED) of a blue and yellow light emitting (structure) layer stacked structure comprises steps of:
growing a buffer layer and an N type gallium nitride epitaxial layer on a sapphire substrate, or gallium nitride substrate, or silicon carbide substrate, or silicon substrate;
growing an N doped AlₐIn_{b}Ga_{1-a-b}N quarternary alloy layer, whose thickness is 1 μm-3 μm, on the N type gallium nitride;
growing a blue light emitting structure layer which contains one or more InₓGa₁₋ₓN/AlₐIn_{b}Ga_{1-a-b}N quantum well(s) on the N type AlₐIn_{b}Ga_{1-a-b}N;
growing a yellow light emitting structure layer which contain one or more In_{y}Ga_{1-y}N/AlₐIn_{b}Ga_{1-a-b}N quantum well(s) on the InₓGa₁₋ₓN/AlₐIn_{b}Ga_{1-a-b}N blue light emitting structure;
growing a P type Al_{0.1}Ga_{0.9}N and a P type GaN cap layer.

8. The method according to claim 7, wherein in the AlₐIn_{b}Ga_{1-a-b}N quarternary alloy, the content of AlN, a, is 0.2-0.3, the content of the InN, b, is 0.1-0.25, and the content of GaN is 1-a-b.

9. The method according to claim 7, wherein in such structure there exists one or more blue light emitting InₓGa₁₋ₓN/AlₐIn_{b}Ga_{1-a-b}N quantum well(s).

10. The method according to claim 7, wherein the content of InN in the InₓGa₁₋ₓN potential well layer, x, is 0.1-0.28; the thickness of the InₓGa₁₋ₓN potential well layer is 1 nm-8 nm; the radio of components of the AlₐIn_{b}Ga_{1-a-b}N potential barrier layer is the same as that of the N type AlₐIn_{b}Ga_{1-a-b}N quarternary alloy, and the thickness thereof is 3-12 nm.

11. The method according to claim 7, wherein in such structure there exists one or more yellow light emitting In_{y}Ga_{1-y}N/AlₐIn_{b}Ga_{1-a-b}N quantum well(s).

12. The method according to claim 7, wherein the content of InN in the In_{y}Ga_{1-y}N potential well layer, y, is 0.3-0.55; the thickness of the In_{y}Ga_{1-y}N potential well layer is 1 nm-8 nm; the ratio of components of the AlₐIn_{b}Ga_{1-a-b}N potential barrier layer is the same as that of the N type AlₐIn_{b}Ga_{1-a-b}N layer, and the thickness thereof is 3-12 nm.
